(19) United States
(12) Patent Application Publication
(10) Pub. No.: US 2009/0199894 A1
(43) Pub. Date: Aug. 13, 2009

(54) Photovoltaic devices protected from environment

(75) Inventors: Dennis Hollars, San Jose, CA (US); David Pearce, Saratoga, CA (US)

Correspondence Address: FOLEY AND LARDNER LLP;SUITE 500, 3000 K STREET NW, WASHINGTON, DC, 20007, US

(73) Assignee: Miasole

(21) Appl. No.: 12/314,519

(22) Filed: Dec. 11, 2008

Related U.S. Application Data
(60) Provisional application No. 61/013,761, filed on Dec. 14, 2007.

(51) Int. Cl. H01L 31/048; H01L 31/18

(52) U.S. Cl. 136/251; 438/66

(57) ABSTRACT

A photovoltaic module includes a first photovoltaic cell, a second photovoltaic cell, and a transparent barrier disposed over the first photovoltaic cell and the second photovoltaic cell. The transparent barrier includes least one inorganic layer and at least one electrical conductor which electrically connects the first photovoltaic cell to the second photovoltaic cell. The transparent barrier may include a flexible sheet, web, foil or ribbon containing at least one glassy layer.

### CROSS REFERENCE TO RELATED PATENT APPLICATIONS

The present application claims benefit of U.S. Provisional Application No. 61/013,761, filed Dec. 14, 2007, which is hereby incorporated by reference in its entirety.

### FIELD

The present invention relates to a field of photovoltaics and, more specifically, to photovoltaic devices protected from the surrounding environment, such as moisture and/or water vapor, and methods of making such devices.

### BACKGROUND

Photovoltaic modules used in residential structures and roofing materials for generating electricity often require additional protection from environmental damage, such as an ingress of water, that can reduce an active lifetime of the photovoltaic system.

Many of commercially available photovoltaic modules utilize organic polymers, such as ethylene vinyl acetate (EVA) for environmental protection. The use of EVA for environmental protection of photovoltaic devices has a number of disadvantages. Firstly, organic peroxide used in EVA manufacturing for cross-linking vinyl acetate is often not completely consumed and the remaining organic peroxide causes a degradation of EVA. Secondly, encapsulation of photovoltaic cells is often carried out in vacuum because oxygen reduces EVA's cross-linking. Thirdly, when contacted with water, EVA can produce acetic acid which can attack and corrode electrodes of photovoltaic cells.

Thus, a need exists to develop alternative ways for environmental protection of photovoltaic cells.

### SUMMARY

In one embodiment, the invention provides a photovoltaic module which includes a first photovoltaic cell, a second photovoltaic cell, and a transparent barrier disposed over the first photovoltaic cell and the second photovoltaic cell. The transparent barrier includes least one inorganic layer and at least one electrical conductor which electrically connects the first photovoltaic cell to the second photovoltaic cell. The transparent barrier may include a flexible sheet, web, foil or ribbon containing at least one glassy layer.

### DRAWINGS

FIG. 1 illustrates a photovoltaic device according to one of the embodiments.

FIG. 2 illustrates a photovoltaic device that has a transparent protective barrier that includes a polymer layer as well as an adhesive layer and an inorganic layer disposed on opposite sides of the polymer layer.

FIG. 3 illustrates a photovoltaic device that has a transparent protective barrier that includes an encapsulating layer over an inorganic layer.

### DETAILED DESCRIPTION

Unless otherwise specified “a” or “an” refer to one or more. The following related patent applications, which are incorporated herein by reference in their entirety, can be useful for understanding and practicing the invention:
1) U.S. patent application Ser. No. 11/451,616 “Photovoltaic Module with Integrated Current Collection and Interconnection” filed Jun. 13, 2006 to Hachtmann et al.;
2) U.S. patent application Ser. No. 11/451,604 “Photovoltaic Module with Insulating Interconnect Carrier” filed Jun. 13, 2006 to Hachtmann et al.;
3) U.S. patent application Ser. No. 11/512,415 “Laminated Photovoltaic Cell” filed Aug. 30, 2006 to Pearce et al.
   The present inventors developed photovoltaic devices that include a transparent protective barrier comprising at least one inorganic layer and at least one electrical conductor and methods of making such devices. The transparent protective barrier can protect one or more photovoltaic cells in the photovoltaic device from surrounding environment such as moisture and/or water vapor, while allowing the Sunlight to reach the one or more photovoltaic cells.

### DEVICE CONFIGURATIONS

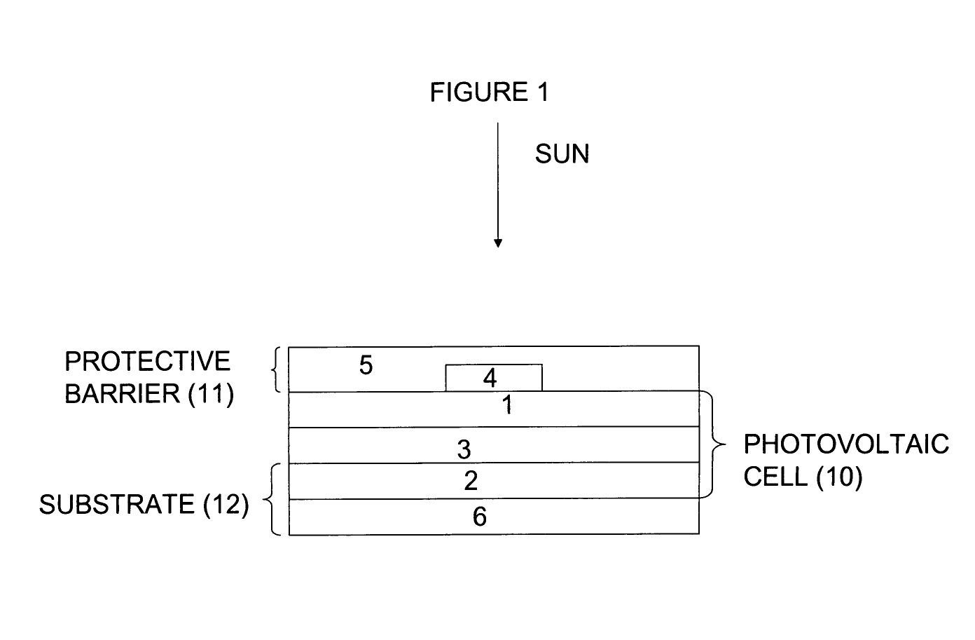

FIGS. 1-3 illustrate several embodiments of the photovoltaic device. The photovoltaic device in FIG. 1 includes a) a photovoltaic cell 10 that includes a first electrode 1 adapted to face the Sun, a second electrode 2 adapted to face away from the Sun and a photovoltaic material 3 disposed between the first and the second electrodes, and b) a transparent protective barrier 11 that includes an inorganic layer 5 and an electric conductor 4. The transparent protective barrier is disposed over the photovoltaic cell so that the conductor 4 electrically contacts the first electrode 1. When the photovoltaic cell is part of a photovoltaic module, the conductor 4 can be used for connecting the photovoltaic cell to another photovoltaic cell in the module. In some cases, the conductor 4 can be a part of a collector-connector as described in U.S. patent applications Ser. Nos. 11/451,616 and 11/451,604.

As used herein, the term “module” includes an assembly of at least two, preferably more photovoltaic cells, such as 3-10,000 cells, for example. The photovoltaic cells of the module can be photovoltaic cells of any type. Each of the photovoltaic cells of the module can be the photovoltaic cell described above. Preferably, the photovoltaic cells of the module are thin film photovoltaic cells. The thin film photovoltaic cells of the module can be located adjacent to each other such that the electrical conductor of the transparent protective barrier provides electrical connection between them.

The photovoltaic device includes a substrate 12. In some cases, the substrate 12 can include a substrate foil or plate 6, on which the second electrode 2 is disposed. In some cases, the electrode 2 material can be eliminated and the substrate 12 can comprise only the conductive plate or foil 6, such as a steel foil. The inorganic layer 5 is preferably a glassy or amorphous layer. In some cases, the inorganic layer 5 can be a self-supporting, i.e. free standing layer. The self-supporting layer can be in a form of a roll, ribbon, web, foil or a sheet. In some cases, the inorganic layer 5 can include one or more thin film inorganic sublayers. In some cases, the transparent protective barrier can also include a support layer (not shown in FIG. 1), such as a polymeric support layer, for supporting the thin film inorganic sublayer(s). The photovoltaic device can include a single thin film inorganic layer or multiple thin film inorganic sublayers of the same or different composition. The photovoltaic device in FIG. 1 can be encapsulated with one or more encapsulating layers (not shown in FIG. 1) over the inorganic layer 5 and/or under the second electrode 2.

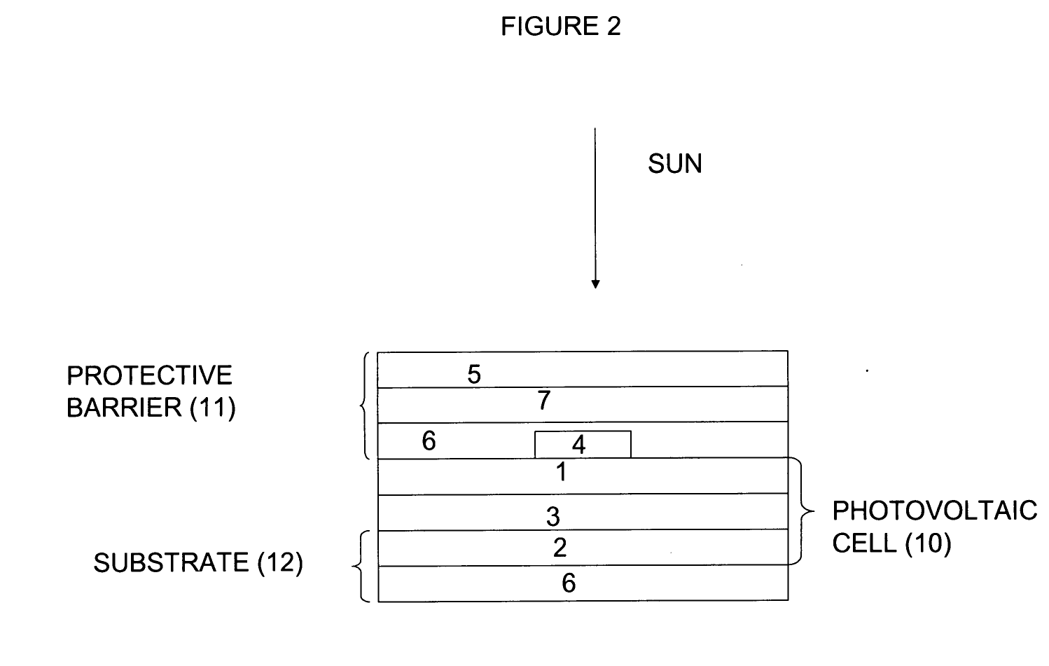

FIG. 2 illustrates a photovoltaic device that includes a) a photovoltaic cell 10 that includes a first electrode I adapted to face the Sun, a second electrode 2 adapted to face away from the Sun and a photovoltaic material 3 disposed between the first and the second electrodes and b) a transparent protective barrier 11 that includes an inorganic layer 5, an electric conductor 4, a polymer support or carrier layer 7 and an adhesive layer 6. The transparent protective barrier can be laminated to the photovoltaic cell through the adhesive layer 6. The adhesive layer 6 and the inorganic layer 5 are disposed on opposite sides of the polymeric support layer 7.

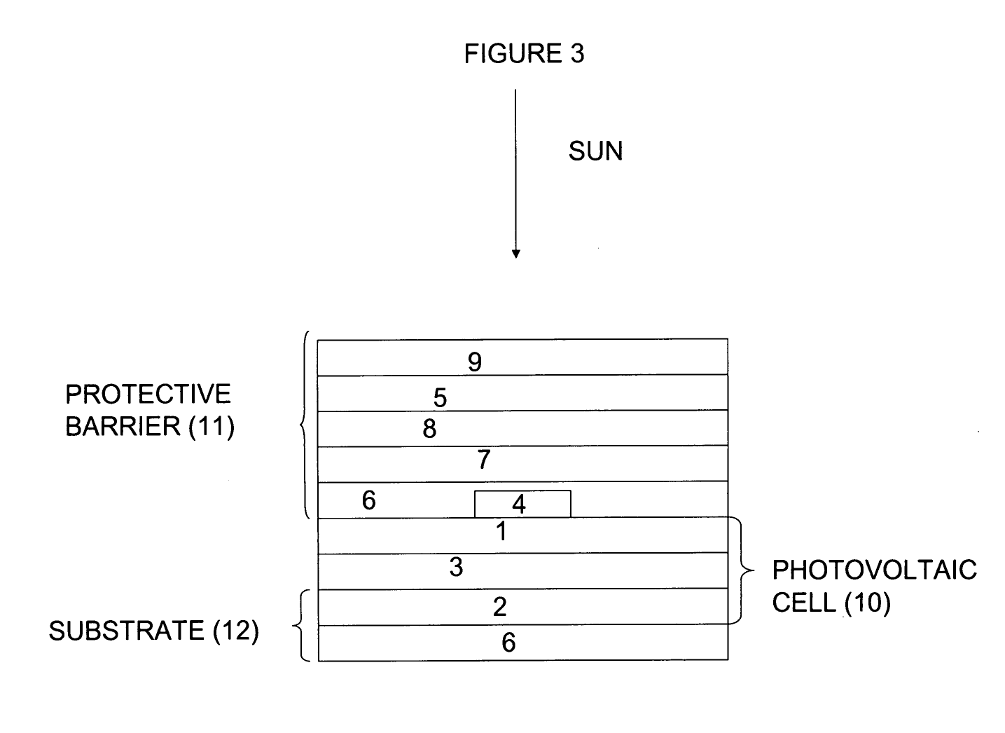

The transparent protective barrier 11 in FIG. 2 can be fabricated prior to being applied to the photovoltaic cell. In some cases, the polymer support layer 7 can be in a roll, ribbon, foil, web or sheet format. The adhesive layer 6 is preferably a thin chemically inert adhesive layer other than EVA. The inorganic layer 5 can be a glassy layer or multiple glassy layers. The inorganic layer can be deposited on a side opposite to the adhesive layer 6 by, for example, sputtering. Sputtering of the inorganic layer in a large deposition machine can be compatible with the polymer supportive layer in a roll, ribbon or sheet format. The electrical conductor 4 can deposited on the adhesive layer. In some cases, the electrical conductor 4 can be fabricated in a form of a grid pattern comprising at least one electrical wire or trace. The grid pattern can be fabricated using a printing technique as a seed layer, upon which a plated layer can deposited using a plating technique. When the photovoltaic device is a module, the electrical conductor 4 can be a part of a collector-connector as described in U.S. patent applications Ser. Nos. 11/451,616 and 11/451,604. The photovoltaic device in FIG. 2 can be encapsulated with one or more encapsulating layers (as shown in FIG. 3) over the inorganic layer 5 and/or under the second electrode 2.

FIG. 3 illustrates a photovoltaic device that includes a) a photovoltaic cell 10 that includes a first electrode 1 adapted to face the Sun, a second electrode 2 adapted to face away from the Sun and a photovoltaic material 3 disposed between the first and the second electrodes and b) a transparent protective barrier 11 that includes an inorganic layer 5, the electric conductor 4, the polymer layer 7, the first adhesive layer 6, a second adhesive layer 8 and an encapsulating layer 9. The second adhesive layer 8 is located between the inorganic layer 5 and the polymer layer 7 and can be used for laminating the layers 5 and 7.

Thus, as discussed above, the transparent protective barrier can include at least one inorganic layer and at least one electrical conductor. The transparent barrier can protect the transparent front side electrode of the photovoltaic cell or the transparent front side electrodes of multiple photovoltaic cells in the module from environmental factors, such as moisture or water vapors.

The transparent barrier can be laminated to the front side electrode of the photovoltaic cell, and as a result, the transparent barrier and the photovoltaic cell can form a unitary structure. For the module embodiment, the transparent protective barrier can be laminated to the front side electrodes of plural photovoltaic cells of the module so that the photovoltaic cells are bonded with the transparent protective layer.

In some embodiments, the at least one inorganic layer can deposited on the side of the transparent polymeric layer that is opposite to the side of the transparent polymeric layer that faces the front side electrode of the photovoltaic cell when the transparent barrier is disposed on the cell. In some embodiments, the at least one inorganic layer can be in direct physical contact with the transparent polymeric layer, yet in some embodiments, an adhesive layer can be present between the at least one inorganic layer and the transparent polymeric layer.

In some embodiments, the transparent protective barrier can have a shape of a flexible ribbon, web, foil, sheet or roll that supports the at least one electrical conductor of the barrier. In some embodiments, the flexible ribbon, web, foil, sheet or roll can be formed by the free-standing glassy layer of the transparent protective barrier, when such free-standing glassy layer comprises a flexible glass, such as Corning 0211 glass or Schott D263 glass. In some embodiments, the flexible ribbon, web, foil, sheet or roll can be formed by the supporting polymeric layer on which the glassy layer is formed.

### PHOTOVOLTAIC CELL MATERIALS

The photovoltaic cell can a photovoltaic cell of any type. Preferably, the photovoltaic cell is a thin-film photovoltaic cell. The photovoltaic cell can include a photovoltaic material, such as a semiconductor material. The photovoltaic semiconductor material may comprise a p-n or p-i-n junction in a Group IV semiconductor material, such as amorphous or crystalline silicon, a Group II-VI semiconductor material, such as CdTe or CdS, a Group I-III-VI semiconductor material, such as CuInSe₂ (CIS) or Cu(In,Ga)Se₂ (CIGS), and/or a Group III-V semiconductor material, such as GaAs or InGaP. The p-n junctions may comprise heterojunctions of different materials, such as CIGS/CdS heterojunction, for example. The cell may also contain front and back side electrodes. These electrodes can be designated as first and second polarity electrodes since electrodes have an opposite polarity. For example, the front side electrode may be electrically connected to an n-side of a p-n junction and the back side electrode may be electrically connected to a p-side of a p-n junction.

The electrode on the front surface of the cell is preferably an optically transparent front side electrode, which is adapted to face the Sun, and may comprise a transparent conductive material, such as indium tin oxide or aluminum doped zinc oxide. The electrode on the back surface of the cell may be a back side electrode, which is adapted to face away from the Sun, and may comprise one or more conductive materials, such as copper, molybdenum, aluminum, titanium, stainless steel and/or alloys thereof. The cell may also comprise the substrate, upon which the photovoltaic material and the front electrode are deposited during fabrication of the cells. In some embodiments, the substrate itself can be the back side electrode. Yet in some embodiments, the backside electrode is deposited on the substrate. In some embodiments, the substrate can be relatively thin, such as less or equal to about 2 mils thick, thereby making the photovoltaic cell light in weight. Other suitable thicknesses may also be used.

In some embodiments, the substrate can be a flexible substrate. Such a flexible substrate can comprise a flexible metal foil, such as a steel foil, when the substrate serves as the back side electrode. When the back side electrode is deposited on the substrate, the flexible substrate can comprise a flexible glass, such as Corning 0211, or a flexible foil-like polymer, such as polyimide.

In some embodiments, the photovoltaic cell can be a plate shaped cell. Yet in some embodiments, the photovoltaic cell may have a square, rectangular (including ribbon shape), hexagonal or other polygonal, circular, oval or irregular shape when viewed from the top.

### TRANSPARENT PROTECTIVE BARRIER MATERIALS

Inorganic Layer. In some embodiments, the at least one inorganic layer can comprise a self-supporting, i.e. free standing, inorganic layer. Such a self supporting inorganic layer can be, for example, a self supporting glassy layer comprising a flexible glass. In some embodiments, a flexible glass can be a flexible borosilicate glass, i.e. a flexible glass comprising SiO₂ and B₂O₃. Various compositions of borosilicate glasses are disclosed for example in U.S. Pat. Nos. 4,870,034, 4,554,259 and 5,547,904, which are incorporated herein by reference in their entirety. Examples of commercially available flexible borosilicate glasses include Corning 0211 flexible glass or Schott D263 glass. Corning 0211 is a thin, lightweight, flexible borosilicate glass available in thicknesses, which can range from 0.05 mm to 0.5 mm. Corning 0211 glass can be doped with various elements so that its optical properties, i.e. transparency window, correspond to the active range of the photovoltaic cell per se. Schott D263 is a thin, lightweight, flexible borosilicate glass available in thicknesses, which can range from 0.03 mm to 1.1 mm. The glass may be coated on a roll in a web coater, and then unrolled from the roll as a foil, ribbon, sheet or web for deposition of the electric conductor. The glass foil, ribbon, sheet or web containing the electric conductor is then attached to the photovoltaic device by using an adhesive material or other attachment methods.

Alternatively, the at least one inorganic layer can comprise one or more oxide layers, such as silicon oxide (SiO₂), aluminum oxide (Al₂O₃) and boron oxide (B₂O₃). The at least one inorganic film can also comprise non-oxide inorganic materials, such as nitrides including SiN. In some embodiments, the deposited at least one inorganic layer can comprise both oxide and non-oxide inorganic materials.

In some embodiments, the transparent barrier can comprise multiple inorganic layers, which can have the same or different composition. In some embodiments, two of the inorganic layers of the transparent barrier can be in a direct physical contact with each other. Yet in some embodiments, the inorganic layers of the transparent barrier can be separated by an organic layer, such as an adhesive layer.

The at least one inorganic layer can be deposited on a carrier film, such as a free standing polymeric carrier film, using a variety techniques including vacuum and non-vacuum thin film deposition techniques. Examples of appropriate thin-film deposition techniques include sputtering, evaporation, chemical vapor deposition, solution based precipitation and/or plating. In some embodiments, the at least one inorganic layer can be deposited using dual rotary magnetron sputtering.

Polymeric Layer. In some embodiments, the transparent protective barrier can include a transparent polymeric layer. The transparent polymeric layer can comprise a chemically inert polymer. Preferably, a material of the transparent polymeric layer is such that it does not degrade significantly by sunlight. Examples of appropriate polymers include fluoropolymers such as polyvinyl fluoride commercially available as Tedlar® or ethylene-tetrafluoro-ethylene polymer commercially available as Tefzel® and polyesters, such as polyethylene terephtalate (PET or PETP) commercially available as Ertalyte®. Other polymers that can be used include thermal polymer olefin (TPO). TPO includes any olefins which have thermoplastic properties, such as polyethylene, polypropylene, polybutylene, etc.

In some embodiments, the thin transparent polymeric layer can be a free standing layer or film, such as a foil, ribbon, roll, web or sheet, and support the at least one inorganic layer and/or the at least one electrical conductor of the transparent barrier.

Adhesive Layer. In some embodiments, the transparent barrier can comprise one or more adhesive layers. In some embodiments, the adhesive layer can be used to laminate the transparent barrier to the front side electrode. Yet in some embodiments, the adhesive layer can be used to laminate one layer of the transparent barrier to another. The adhesive layer can be also used for laminating the at least one inorganic layer to the transparent polymeric layer.

In some embodiments, the adhesive layer may comprise ethyl vinyl acetate (EVA) or other adhesive, such as room temperature vulcanized silicones (RTV silicones) or polyisobutylene rubber (butyl rubber). In some embodiments, an adhesive more chemically inert than EVA may be preferred for an adhesive layer directly contacting a transparent electrode of the photovoltaic cell.

Encapsulating Layer. In some embodiments, the transparent protective barrier can comprise an encapsulating layer. Such a layer may be a layer furthest from the photovoltaic cell per se when the transparent barrier is disposed on the front side electrode. The encapsulating layer can be disposed directly on one of the inorganic layers of the transparent barrier or alternatively the encapsulating layer can be laminated to one of the inorganic layers of the transparent barrier through an adhesive layer comprising EVA or another adhesive. The encapsulating layer can comprise chemically resistant fluoropolymer, such as ethylene-tetrafluoro-ethylene commercially available as Tefzel®.

In some embodiments, the photovoltaic devices can include a bottom encapsulating layer which can encapsulate a particular device at the bottom, i.e. at the side of the photovoltaic device facing away from the Sun. Both the encapsulating layer of the transparent protective barrier and the bottom encapsulating layer can have a shape of a ribbon, a sheet or a roll.

Electrical Conductor. The at least one electrical conductor of the transparent protective barrier can comprise any electrically conductive material, such as metals including copper, aluminum, gold, nickel, silver, cobalt or electrically conductive carbon.

In some embodiments, the at least one electrical conductor can be disposed on one of the inorganic layers of the transparent barrier. Yet in some embodiments, the at least one electrical conductor can be disposed on the adhesive layer laminating the transparent barrier to the photovoltaic cell per se.

The electrical conductor can be comprise any electrically conductive trace or wire. In some embodiments, the electrical conductor can form an electrically conductive grid.

In some embodiments, the electrical conductor can be deposited on the transparent barrier as a conductive trace using a printing or plating technique, such as screen printing, pad printing, ink jet printing electro or electroless plating. In some embodiments, the conductive trace can comprise a conductive paste, such as a silver paste, i.e. a polymer-silver powder mixture paste spread using a printing technique. In some embodiments, the conductor can be a multilayer trace. Such a multilayer trace can comprise a seed layer and a plated layer. The seed layer may comprise any conductive material, such as a silver filled ink or a carbon filled ink, which can be printed in a desired pattern. The seed layer can be formed by a high speed printing technique such as rotary screen printing, flat bed printing, rotary gravure printing, etc. The plated layer may be comprise any conductive material which can be formed by plating such as copper, nickel, cobalt and their alloys. The plated layer can be formed by plating using the seed layer as one of the electrodes in a plating bath. Alternatively, the plated layer may be formed by electroless plating.

Although the foregoing refers to particular preferred embodiments, it will be understood that the present invention is not so limited. It will occur to those of ordinary skill in the art that various modifications may be made to the disclosed embodiments and that such modifications are intended to be within the scope of the present invention. All of the publications, patent applications and patents cited herein are incorporated herein by reference in their entirety.

What is claimed is:

1. A photovoltaic module, comprising
a first photovoltaic cell;
a second photovoltaic cell;
a transparent barrier disposed over the first photovoltaic cell and the second photovoltaic cell, wherein:
the transparent barrier comprises at least one inorganic layer and at least one electrical conductor which electrically connects the first photovoltaic cell to the second photovoltaic cell.

2. The photovoltaic module of claim 1, wherein:
the at least one inorganic layer comprises a flexible sheet, web, foil or ribbon supporting the at least one electrical conductor; and
the at least one electrical conductor comprises an electrically conductive wire or trace.

3. The photovoltaic module of claim 2, wherein the at least one inorganic layer comprises at least one glassy layer.

4. The photovoltaic module of claim 3, wherein the at least one glassy layer comprises at least one sputtered glassy layer.

5. The photovoltaic module of claim 4, further comprising a flexible polymer layer supporting the at least glassy layer and the at least one electrically conductive wire or trace.

6. The photovoltaic module of claim 3, wherein the at least one inorganic layer comprises a self-supporting flexible glassy layer.

7. The photovoltaic module of claim 2, wherein the transparent barrier comprises a collector-connector adapted to collect current from the first photovoltaic cell and which electrically connects the first photovoltaic cell to the second photovoltaic cell.

8. The photovoltaic module of claim 2, wherein the first and the second photovoltaic cells comprise plate shaped cells which are located adjacent to each other and wherein the transparent barrier is laminated to the first and second photovoltaic cells.

9. The photovoltaic module of claim 8, further comprising an adhesive layer that adheres the transparent barrier to the first and second photovoltaic cells.

10. The photovoltaic module of claim 8, wherein each of the first and the second photovoltaic cells comprises a transparent first polarity electrode adapted to face the Sun and the transparent barrier is laminated to the first polarity electrode of each of the first and second photovoltaic cells.

11. The photovoltaic module of claim 8, wherein the first and the second photovoltaic cells comprise flexible photovoltaic cells.

12. A photovoltaic device, comprising:
a photovoltaic cell, comprising:
a transparent first polarity electrode adapted to face the Sun,
a substrate comprising a second polarity electrode adapted to face away from the Sun, and
a photovoltaic material disposed between the first and second polarity electrodes; and
a transparent barrier comprising a flexible sheet, web, foil or ribbon comprising at least one glassy layer supporting the at least one electrical conductor, wherein the transparent barrier is laminated to the photovoltaic cell so that the at least one electrical conductor electrically contacts the first polarity electrode.

13. The photovoltaic cell of claim 12, wherein the at least one electrical conductor comprises at least one electrically conductive wire or trace.

14. The photovoltaic cell of claim 12, wherein the at least one glassy layer comprises at least one sputtered glassy layer.

15. The photovoltaic cell of claim 14, wherein the transparent barrier further comprises a flexible polymer layer supporting the at least one glassy layer and the at least one electrical conductor.

16. The photovoltaic cell of claim 15, further comprising an encapsulating layer disposed over the transparent barrier.

17. The photovoltaic cell of claim 14, wherein the at least one glassy layer comprises a self-supporting flexible glassy layer.

18. The photovoltaic cell of claim 12, further comprising an adhesive layer adhering the transparent barrier to the first polarity electrode.

19. A method of making a photovoltaic device comprising
providing a photovoltaic cell comprising
a transparent first polarity electrode,
a second polarity electrode, and
a photovoltaic material disposed between the first polarity electrode and the second polarity electrode;
providing a transparent protective barrier comprising at least one inorganic layer and at least one electrical conductor; and
laminating the transparent protective barrier to the first polarity electrode so that the at least one conductor electrically contacts the first polarity electrode.

20. The method of claim 19, wherein the providing the transparent protective barrier comprises:
providing a flexible polymer layer having a first surface and a second surface,
depositing at least one inorganic layer over the first surface of the flexible polymer layer; and
depositing at least one electrically conductive wire or trace on the second surface of the second surface of the polymer layer.
